(19) United States
(12) Patent Application Publication
(10) Pub. No.: US 2025/0392255 A1
(43) Pub. Date: Dec. 25, 2025

(54) VERTICAL INSTALLATION FOR POWER GENERATION BY MEANS OF PHOTO-VOLTAICS

(71) Applicant: Martin WAKONIG, Wien (AT)

(72) Inventor: Martin WAKONIG, Wien (AT)

(21) Appl. No.: 18/879,316

(22) PCT Filed: Jun. 30, 2023
(86) PCT No.: PCT/AT2023/060208

§ 371 Date: Dec. 27, 2024

(30) Foreign Application Priority Data
Jul. 1, 2022 (AT) A 50484/2022

(51) Int. Cl. H02S 40/36; H02S 20/21

(52) U.S. Cl. CPC H02S 40/36; H02S 20/21

(57) ABSTRACT

An installation for power generation by means of photovoltaics, wherein the installation includes at least four solar modules, wherein the solar modules are distributed over at least two solar surfaces so that each solar surface includes at least two solar modules, wherein the solar surfaces are arranged vertically one above the other in a parallel offset manner, wherein the solar modules are connected in at least two strings, wherein each of the at least two strings includes at least one solar module on at least two different solar surfaces, wherein each string is assigned a utilization depth, wherein the utilization depth corresponds to the maximum distance of the solar modules of the string from an outer edge of the solar surface of the respective solar module, and wherein the strings include at least two different utilization depths.

The invention relates to an installation for power generation by means of photovoltaics, wherein the installation comprises at least four solar modules, wherein the solar modules are distributed over at least two solar surfaces, so that each solar surface comprises at least two solar modules, wherein the solar surfaces are arranged vertically one above the other in a parallel offset manner.

When generating electricity by means of photovoltaics for the supply of not only small devices, such as wristwatches or radios, it is necessary to use a large number of solar modules in order to achieve the required power level. The solar modules can be arranged in a single solar surface, for example horizontally. Depending on the location of the installation and the available area, it is advantageous to divide the solar modules into several, typically parallel offset solar surfaces. This enables, for example, an optimal orientation of the solar surfaces toward the mean angle of sunlight. The solar surfaces are arranged vertically one above the other in order to reduce the footprint of the installation. Regardless of the direction in which the solar surfaces are arranged in parallel offset, a balance must be struck between the optimal use of incoming sunlight and the occasional mutual shading of the solar surfaces. Completely avoiding shading at every time of day simultaneously means that at many times of day, and especially at the highest position of the sun-and thus at maximum light intensity-some of the incident sunlight remains unused. Conversely, making the most complete possible use of incident light at the highest position of the sun and at the optimal angle of incidence simultaneously means that at other times of day parts of the installation are shaded.

In practice, it is not economical to connect each solar module individually or even in parallel to an inverter. The wiring and installation effort required for this would be disproportionately high. Therefore, as a rule, several solar modules are connected in series and connected together to an inverter. The disadvantages of shading solar modules in the case of such a series connection are known. In particular, each solar module is usually combined with a freewheeling diode (i.e. connected in parallel) to protect it from the power of the other solar modules in the series in the event of shading or a defect. Although the shaded solar module still receives radiation energy and could therefore provide PV power (albeit to a lesser extent), this power is lost.

Furthermore, U.S. Pat. No. 4,966,631 A proposes coordinating the arrangement of the series-connected solar modules with an expected shadow path, for example parallel to the earth's surface.

JP 2002-061126 A shows a noise barrier with vertical photovoltaics, with additional slanted PV elements arranged below. The modules are connected in strings that run offset in parallel in the direction of travel and can extend over both solar surfaces. The shadow of a passing car is always supposed to affect only part of the strings.

US 2014/028104 A1 shows parallel solar surfaces. However, the sub-strings are limited to the individual solar surfaces and each wired to its own inverter.

In DE 10 2019 008062 A1, EP 3 007 234 A1, and US 2018/323639 A1, only strings within a single solar surface are likewise shown in each case.

JP 2021-145496 A shows a photovoltaic open-area installation (also called a solar park). In this, the solar surfaces are naturally arranged exclusively horizontally offset in the open area. It is thus a different type of installation than the one in the present disclosure.

It is an object of the invention to avoid or reduce efficiency losses of the installation due to different shading of the solar modules over the course of the day and at the same time to reduce the wiring effort between the individual solar surfaces and the inverter.

The solution according to the invention provides that the solar modules are connected in at least two strings, wherein each of the at least two strings comprises at least one solar module on at least two different solar surfaces, wherein a utilization depth is assigned to each string, wherein the utilization depth corresponds to the maximum distance of the solar modules of the string from an outer edge of the solar surface of the respective solar module, and wherein the strings comprise at least two different utilization depths.

Colloquially, the terms “solar panel” and “solar module” are not clearly defined and are occasionally used synonymously in German, while in English different meanings of “solar panel” and “solar module” are common. For the sake of clarity, the terms “solar panel” and “solar module” are defined separately and not used synonymously in this disclosure. A solar module comprises one or more solar cells. In this disclosure, a solar module is understood to be a combination of one or more solar cells that provides the total power of the combined solar cells via a common two-pole electrical connection. A solar module is the smallest electrically connected unit. Of course, additional poles of the electrical connections can be provided for purposes other than the transmission of electrical power. The solar cells within the solar module can be connected in series and/or in parallel. Within a solar surface, the solar modules can be embedded into larger structures. For example, the solar modules can be mechanically embedded in solar panels. A solar panel is a mechanical structural unit. Within a solar panel, several solar modules can be arranged, e.g. geometrically parallel. A solar panel can have several “outputs,” which are electrical connections designed for transmitting electrical power. In this case, each output corresponds to a solar module. A solar panel with multiple outputs thus comprises multiple solar modules and is therefore not itself a “solar module.” Several solar panels can in turn be arranged in rows or arrays. The strings can coincide with the panels, rows, or arrays or can subdivide them. For example, it is generally conceivable that the solar modules of a panel, a row, or an array belong to the same string or to different strings. Each solar module can belong to only one string.

Due to the different utilization depths, the solar modules are shaded at different times and to different extents over the course of the day. The utilization depth refers within the string to the solar module or the solar modules with the greatest distance from an outer edge of the respective solar surface. i.e. the distance is determined between the solar module and the outer edge in the solar surface in which the solar module is arranged. In the case of parallel solar surfaces, the extent of shading of the solar surfaces can naturally be the same or similar, particularly if the solar surfaces are arranged at uniform distances in a structure with three or more surfaces. The effect of the invention is generally also achieved for solar surfaces deviating from exact parallelism. As long as a substantially simultaneous development of shading over the course of the day is achieved, i.e. a corresponding extent of shading at various times throughout the day, the solar surfaces are to be regarded as parallel within the meaning of the claims and are covered by the present disclosure.

Assuming all identical solar modules, the reference point of the solar module for determining the distance (and thus the utilization depth) is irrelevant, since the distance is only relevant as a relative measure. If solar modules with different geometries are used, the decisive factor for determining the utilization depth would be that distance measured between the point of the solar module farthest from the outer edge of the solar surfaces (“deepest” point) and the outer edge.

The different utilization depths mean that the string with the smaller utilization depth can deliver relatively higher power than if only a single string per solar surface or multiple strings with the same (i.e. equally large) utilization depth were used. In this way, the efficiency loss of the installation due to shading over the course of the day is reduced.

Due to the arrangement of the solar surfaces vertically one above the other in a parallel offset manner, the shading effect is greater the closer the direction of the sunlight over the course of the day comes to a vertical. At the same time, at relatively high solar altitude over the course of the day, the fundamentally achievable power is also greatest (assuming the solar surfaces are optimally oriented accordingly). At relatively low solar altitude over the course of the day, when no significant self-shading of the solar surfaces (i.e. the shadow of one solar surface falls on an adjacent solar surface and partially or completely shades it) is to be expected due to the vertical arrangement, the fundamentally achievable power is also considerably lower than at a relatively high solar altitude. In other words, with the vertical arrangement disclosed here, the effect of self-shading sets in at a basically higher power level due to the solar altitude than would be the case with a horizontal arrangement, in which self-shading increases as the solar altitude decreases. In simple terms, the shadow contrast at the solar zenith is stronger than at a lower solar altitude. This results in a more significant power difference depending on the utilization depth of the solar modules than would be the case with a horizontal arrangement. It is therefore more important for the vertical arrangement than for a horizontal arrangement to avoid or reduce the disadvantage of this power difference with the circuitry disclosed here.

Optionally, each string can be a series connection of individual solar modules. Typically, one freewheeling diode (or bypass diode) is connected in parallel to each solar module. The freewheeling diode prevents the entire string from having to be disconnected in the event of a defect in the associated solar module.

In this configuration, for example, all solar modules of a string can comprise the same distance from an outer edge of the solar surface of the respective solar module. Accordingly, all solar modules within this string experience the same degree of shading by a parallel offset solar surface. All solar modules within this string can thus be operated at the same reduced power level, in particular supply the same reduced current, so that each individual solar module is optimally operated in relation to its own shading. Depending on the extent of shading, the power level can differ significantly between the different strings.

According to an alternative optional configuration, each string can be a series connection of parallel-connected groups of solar modules. Typically, one blocking diode is connected in series to each solar module. The blocking diode prevents the output voltage of the entire group from collapsing in the event of a defect in the associated solar module.

In this alternative configuration, for example, all groups of a string can comprise the same utilization depth, wherein the utilization depth of a group corresponds to the maximum distance of the group's solar modules from an outer edge of the solar surface of the respective solar module. Within the parallel-connected group, a reduction in the current supplied by individual group members (i.e. individual solar modules within the group) can be accepted, because the current supplied by the other group members is not restricted by this. However, the total current of the individual series-connected groups should each be the same in order to make the best possible use of the power of the non-shaded group members. Therefore, the distribution of the distances of the individual group members to the outer edge of the respective solar surface can be the same for all groups. It turns out that with this configuration, the efficiency of the installation can be increased by up to 40%, depending on the arrangement of the solar surfaces.

According to an optional exemplary embodiment, at least two solar modules of a solar surface can be arranged mechanically connected in one panel, wherein the panel comprises at least two electrical connections, wherein each electrical connection is connected to at least one solar module, so that the solar modules of the panel can be connected via different, separate connections. The combination of several solar modules facilitates manufacturing, handling, and installation.

In this context, it can be provided in particular that each solar module of the panel comprises exactly one row of solar cells, wherein the rows of the at least two solar modules are arranged in parallel. In this way, the minimum width of a row is achieved for a given geometry of the solar cells. Thus, all solar cells of one row operate at the same operating point during parallel shading by an adjacent, parallel surface or solar surface (i.e. parallel to the outer edge) and thus supply the same power. Each cell supplies the same possible current, and no power is lost due to the series connection of cells.

The outer edges of the solar surfaces of the installation can optionally lie in an imaginary connecting plane, wherein the imaginary connecting plane encloses an angle of 90° with a horizontal. The solar surfaces enclose, at the outer edges, an angle greater than 0° with the imaginary connecting plane. Thus, the solar surfaces do not lie in a common plane. The imaginary connecting plane is a vertical plane, with the lowest possible footprint of the installation. A vertical imaginary connecting plane is present if this disclosure is used on a noise barrier for power generation by means of photovoltaics. In this case, for example, the solar surfaces can be formed by the top sides of the lamellae of the noise barrier. The noise barrier can, for example, be constructed from wall elements as in WO 2020/056441 A1, with the properties disclosed therein. The efficiency losses due to shading are greater with these configurations and conventional wiring of the solar modules than would be the case with a horizontal imaginary connecting plane, so the benefit of the invention in reducing these losses is particularly evident here.

The at least two strings can be connected to different inverters or to independent inputs of one inverter. The strings generally supply different currents. To use the supplied current as efficiently as possible, a separate inverter conversion can therefore be provided. Optionally, the inverter outputs can be connected in parallel to combine the output power of the individual strings after the inverter or inverters. In particular, the string connections can each go to independent Maximum Power Point (MPP) trackers, which can be integrated in the inverter or the inverters, for example.

The invention is further explained below on the basis of particularly preferred exemplary embodiments, to which it is not limited, and with reference to the drawings. The drawings show in detail:

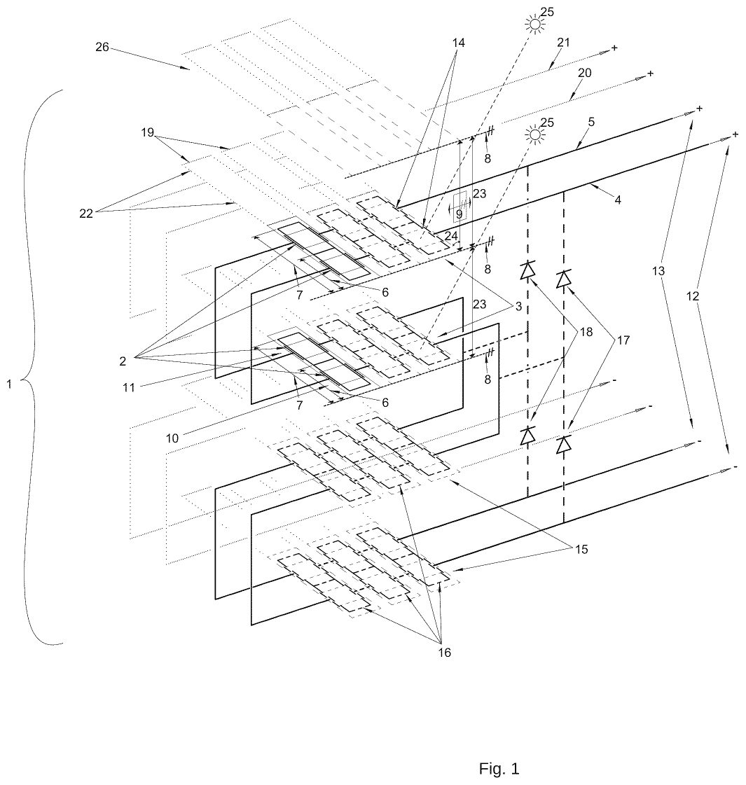

FIG. 1 schematically shows the structure of an installation according to a first exemplary embodiment of this disclosure with four solar surfaces arranged in parallel offset.

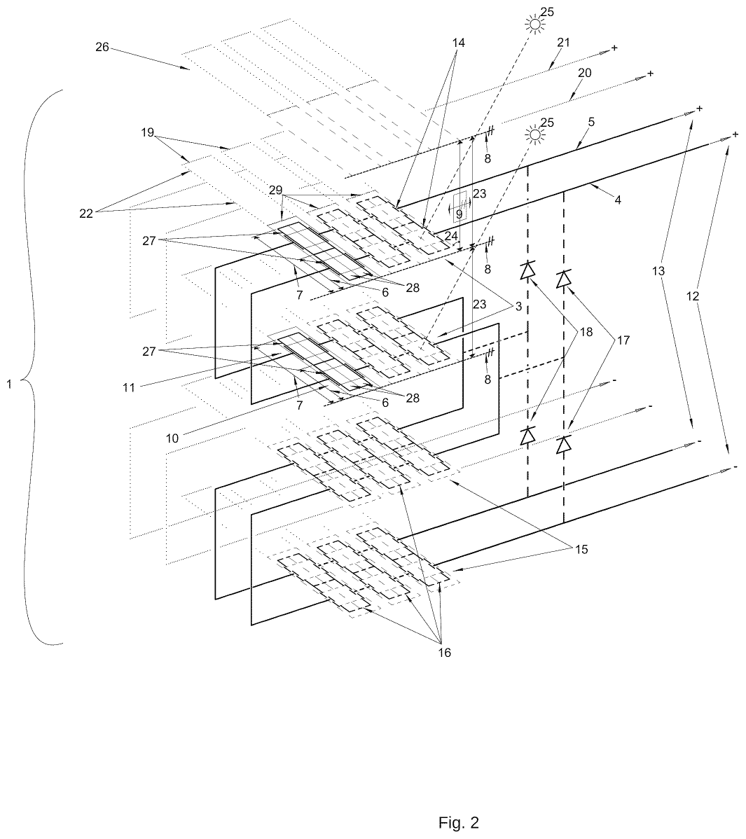

FIG. 2 schematically shows the structure of an installation according to a second exemplary embodiment of this disclosure, wherein in each case two series-connected solar modules form a panel.

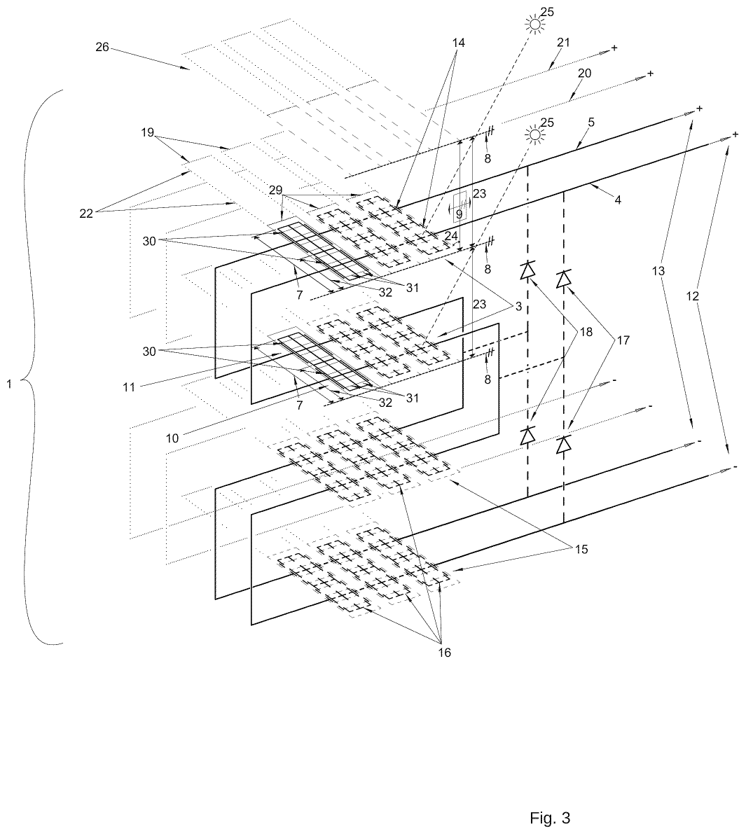

FIG. 3 schematically shows the structure of an installation according to a third exemplary embodiment of this disclosure, wherein in each case two parallel-connected groups with in each case two series-connected solar modules form a panel.

FIG. 1 shows an installation 1 for power generation by means of photovoltaics. In a basic configuration (solid lines), the installation comprises four solar modules 2. The four solar modules 2 are distributed over two solar surfaces 3. Each solar surface 3 comprises two solar modules 2. The solar surfaces 3 are arranged in parallel offset. In this basic configuration, the solar modules 2 are connected in two strings 4, 5. Each of the two strings 4, 5 comprises one solar module 2 on each of the two solar surfaces 3. Each string 4, 5 is a series connection of individual solar modules 2. Each string 4, 5 is assigned a utilization depth 6, 7.

The utilization depth 6, 7 corresponds to the maximum distance of the solar modules 2 of the respective string 4, 5 from an outer edge 8 of the solar surface 3 of the respective solar module 2. The outer edges 8 of the solar surfaces 3 lie here in an imaginary connecting plane 9. The imaginary connecting plane 9 is a vertical plane in this exemplary embodiment. The solar surfaces 3 are, for example, mounted on the top sides of corresponding lamellae of a noise barrier. The two strings 4, 5 comprise different (therefore two) utilization depths 6, 7. In this exemplary embodiment, all solar modules 2 of a string 4, 5 comprise the same distance from an outer edge 8 of the solar surface 3 of the respective solar module 2. Accordingly, in this case, the solar modules 2 of a string 4, 5 all supply the same current per string.

In the lamella-like arrangement of solar modules 2 shown here with multiple parallel arranged module rows 10, 11 of solar modules 2, individual module rows 10 of a lamella with a smaller distance to the open sky receive more radiant energy than those module rows 11 with a greater distance. If lamellae are arranged in such a way that at certain times of day with direct sunlight there is self-shading of individual module rows 10, 11 within the lamellae, the difference in radiant energy of module rows 10, 11 with different distances to the open sky becomes even more pronounced. Within a lamella, if the adjacent, parallel arranged module rows 10, 11 with different distances to the open sky are connected together in a series circuit, all module rows would only deliver the power of the module row 11 receiving the least radiant energy. If freewheeling diodes are arranged per module row, one or more module rows with lower power or partial shading are completely switched off. This loss becomes even more evident, especially with lamella-like arrangements of multi-row solar modules with a small distance between the lamellae or arranged vertically or obliquely above each other.

In the first exemplary embodiment shown in FIG. 1, the two strings 4, 5 are connected with the electrical connections 12, 13 to different inverters or to independent inputs of one inverter. More precisely, each string 4, 5 is connected to its own MPP tracker. This makes it possible to determine and utilize the optimal power level for each string 4, 5.

Apart from the basic configuration, several extended configurations are illustrated in FIG. 1. In dashed lines, a first extended configuration is shown with an additional four solar modules 14 per solar surface 3 as well as two further solar surfaces 15, also each comprising six solar modules 16. In total, in this first extended configuration, twelve solar modules 2, 14, 16 are connected in series per string 4, 5. Within each string 4, 5, freewheeling diodes 17, 18 can additionally be provided, each for example bridging an upper or lower half of the string 4, 5. This makes it possible, in the event of a failure of part of the string 4, 5, to continue using the other half. This can be useful, for example, in the event of contamination or mechanical damage in the lower area of a noise barrier, in order to possibly switch off complete solar surfaces across all strings.

A second extended configuration is illustrated in dotted lines in FIG. 1. In this case, six more solar modules 19 are schematically indicated per solar surface 3, 15, doubling the number of solar modules compared to the first extended configuration. The additional solar modules 19 are arranged at a greater utilization depth and accordingly connected in two additional strings 20, 21 in series. The possibility and efficiency of such additional module rows 22 depends on the distance 23 between the solar surfaces 3, 15 as well as on the angle 24 between the solar surfaces 3, 15 and the imaginary connecting plane 9, relative to the angle of incidence of the sunlight 25. The greater the distance 23, the more beneficial extended utilization depths and corresponding strings become.

Schematically, an uppermost solar surface 26 is indicated for all configurations in FIG. 1. Naturally, it is not affected by shading effects. Therefore, in a conventional manner, all solar modules on the uppermost solar surface 26 can be connected in a common series connection regardless of their distance to the outer edge 8 and all connected together to a separate inverter connection.

In the second exemplary embodiment shown in FIG. 2, panels 27 each comprising two series-connected solar modules 28 are connected in series per string 4, 5. The panels 27 are combined into arrays 29 that extend perpendicular to the outer edge 8. Thus, the individual panels 27 of an array 29 comprise different utilization depths 6, 7 and therefore belong to different strings 4, 5 according to this exemplary embodiment. Otherwise, the second exemplary embodiment corresponds to the first exemplary embodiment and uses the same reference signs.

The third exemplary embodiment shown in FIG. 3 differs from the first exemplary embodiment in particular in that each string 4, 5 is a series connection of parallel-connected groups 30 of solar modules 31. All groups 30 of a string 4, 5 comprise the same utilization depth 32, 33. The utilization depth 32, 33 of a group 30 corresponds to the maximum distance of the solar modules 31 of the group 30 from an outer edge 8 of the solar surface 3 of the respective solar module 31. This maximum distance is determined by the “deepest” solar module 31 of the group 30. To avoid repetition, reference is made to the explanations of the first exemplary embodiment and FIG. 1 regarding the other features in FIG. 3.

What is claimed is:

1. An installation (1) for power generation by means of photovoltaics, wherein the installation (1) comprises at least four solar modules (2), wherein the solar modules (2) are distributed over at least two solar surfaces (3) so that each solar surface (3) comprises at least two solar modules (2), wherein the solar surfaces (3) are arranged vertically one above the other in a parallel offset manner,
wherein the solar modules (2) are connected in at least two strings (4, 5), wherein each of the at least two strings (4, 5) comprises at least one solar module (2) on at least two different solar surfaces (3), wherein each string (4, 5) is assigned a utilization depth (6, 7), wherein the utilization depth (6, 7) corresponds to the maximum distance of the solar modules (2) of the string (4, 5) from an outer edge (8) of the solar surface (3) of the respective solar module (2), and wherein the strings (4, 5) comprise at least two different utilization depths (6, 7).

2. The installation (1) according to claim 1, wherein each string (4, 5) is a series connection of individual solar modules (2).

3. The installation (1) according to claim 2, wherein all solar modules (2) of a string (4, 5) comprise the same distance from an outer edge (8) of the solar surface (3) of the respective solar module (2).

4. The installation (1) according to claim 1, wherein each string (4, 5) is a series connection of parallel-connected groups (30) of solar modules (31).

5. The installation (1) according to claim 4, wherein all groups (30) of a string (4, 5) comprise the same utilization depth (32, 33), wherein the utilization depth (32, 33) of a group (30) corresponds to the maximum distance of the solar modules (31) of the group (30) from an outer edge (8) of the solar surface (3) of the respective solar module (31).

6. The installation (1) according to claim 1, wherein at least two solar modules of a solar surface are arranged mechanically connected in a panel, wherein the panel comprises at least two electrical connections, wherein each electrical connection is connected to at least one solar module, so that the solar modules of the panel can be connected via different, separate connections.

7. The installation (1) according to claim 6, wherein each solar module of the panel comprises exactly one row of solar cells, wherein the rows of the at least two solar modules are arranged in parallel.

8. The installation (1) according to claim 1, wherein the outer edges (8) of the solar surfaces (3) lie in an imaginary connecting plane (9), wherein the imaginary connecting plane (9) encloses an angle of 90° with a horizontal.

9. The installation (1) according to claim 1, wherein the at least two strings (4, 5) are connected to different inverters or to independent inputs of an inverter.

10. A noise barrier, wherein an installation according to claim 1 is installed on the noise barrier.
